(19) United States
(12) Patent Application Publication
(10) Pub. No.: US 2026/0082710 A1
(43) Pub. Date: Mar. 19, 2026

(54) METHOD AND SYSTEM FOR HANDLING RADIATION IN LONG-WAVELENGTH AND FAR INFRARED RANGE

(71) Applicant: Ramot at Tel-Aviv University Ltd., Tel-Aviv (IL)

(72) Inventor: Itai EPSTEIN, Tel-Aviv (IL)

(73) Assignee: Ramot at Tel-Aviv University Ltd., Tel-Aviv (IL)

(21) Appl. No.: 19/107,194

(22) PCT Filed: Aug. 28, 2023
(86) PCT No.: PCT/IL2023/050912

§ 371 Date: Feb. 27, 2025

Related U.S. Application Data
(60) Provisional application No. 63/401,666, filed on Aug. 28, 2022.

(51) Int. Cl. H10F 30/28; H10F 77/122; H10F 77/40; H10H 20/00

(52) U.S. Cl. CPC H10F 30/2823; H10F 77/122; H10F 77/413; H10H 20/062

(57) ABSTRACT

An optoelectronic device comprises a gapped graphene system (GGS) a top gate electrode, a bottom gate electrode and a controller configured for applying a voltage bias between the gate electrodes to effect a bandgap in the GGS, wherein the bandgap is selected to allow the GGS to receive or emit light having a terahertz frequency.

### RELATED APPLICATION

This application claims the benefit of priority of U.S. Provisional Patent Application No. 63/401,666 filed on Aug. 28, 2022, the contents of which are incorporated herein by reference in their entirety.

### FIELD AND BACKGROUND OF THE INVENTION

The present invention, in some embodiments thereof, relates to a handling of radiation and, more particularly, but not exclusively, to a method and system for emitting and/or detecting radiation in the terahertz (THz) range, preferably the long-wavelength-infrared (LWIR) range and the far-infrared (FIR) range.

Radiation in LWIR range preferably includes an optical filed having a frequency of from about 20 THz to about 35 THz. Radiation in the FIR range preferably includes an optical filed having a frequency of from about 0.5 THz to about 20 THz.

In recent years, efforts have been invested to improve THz technologies, by employing liquid-helium cooling (see, e.g., U.S. Pat. No. 8,274,058) and/or femto-second lasers (see, e.g., 10,408,679). In the LWIR range, there are commercially available spectroscopic system such as Fourier transform infrared (FTIR) spectroscopy systems that are routinely used for laboratory chemical identification (see, e.g., U.S. Pat. No. 9,638,630 and U.S. Published Application No. 20220205904).

### SUMMARY OF THE INVENTION

According to an aspect of some embodiments of the present invention there is provided an optoelectronic device. The optoelectronic device comprises a gapped graphene system (GGS) a top gate electrode, a bottom gate electrode and a controller configured for applying a voltage bias between the gate electrodes to effect a bandgap in the GGS, wherein the bandgap is selected to allow the GGS to receive or emit light having a frequency within the range of from about 0.5 THz to about 35 THz.

According to some embodiments of the invention the optoelectronic device comprises an optical cavity.

According to some embodiments of the invention the optoelectronic device comprises at least two optical cavities, each being characterized by a different resonance frequency.

According to some embodiments of the invention each optical cavity has a different Q factor.

According to some embodiments of the invention the GGS is connected to an end of the optical cavity via van der Waals forces.

According to some embodiments of the invention the controller is configured to scan the voltage bias, so as to vary the bandgap.

According to some embodiments of the invention the GGS is encapsulated in a dielectric encapsulation.

According to an aspect of some embodiments of the present invention there is provided an optical detector. The optical detector comprises the optoelectronic device as delineated above and optionally and preferably as further detailed below. The optical detector also comprises a source electrode and a drain electrode connected to the GGS.

According to an aspect of some embodiments of the present invention there is provided a camera. The camera comprises an image processor and the optical detector as delineated above and optionally and preferably as further detailed below, wherein the controller is configured to spatially scan an object or a scene to detect radiation from each of multiple points over the object or scene, thereby providing an array of detection signals, and wherein the image processor is configured to generates from the array of detection signals an image of the object or scene.

According to an aspect of some embodiments of the present invention there is provided a camera. The camera comprises an image processor, an array of optical detectors as delineated above and optionally and preferably as further detailed below, and optics configured to focus radiation from each of multiple points over the object or scene onto a different optical detector of the array, wherein the image processor is configured to receive a respective array of detection signals from the array of detectors and to generate from the array of detection signals an image of the object or scene. In these embodiments, the array of optical detectors serves as a pixelated imager in which each detector or group of detectors provides a separate signal corresponding to a separate picture-element of the image, preferably a single pixel of the image.

According to some embodiments of the invention the image processor is configured to receive a plurality of arrays of detection signals, each corresponding to a different frequency of the radiation, and to generate the from a combination of the arrays of detection signals.

According to some embodiments of the invention the plurality of arrays of detection signals are transmitted serially to the image processor.

According to some embodiments of the invention at least two of the plurality of arrays of detection signals are transmitted simultaneously to the image processor from a respective two optical detectors each configured to detect light at a different frequency range.

According to an aspect of some embodiments of the present invention there is provided a light source. The light source comprises the optoelectronic device as delineated above and optionally and preferably as further detailed below, and a pumping device configured to generate in the GGS electron-hole pairs which emit light upon recombination.

According to some embodiments of the invention the pumping device comprises a source electrode and a drain electrode connected to the GGS, and wherein the controller is also configured to inject electrical current into the GGS via the source and drain electrodes, thereby to electrically pump the GGS.

According to some embodiments of the invention the pumping device comprises a laser source configured to irradiate the GGS to optically pump the GGS.

According to some embodiments of the invention the light source comprises a cooling system configured to liquid-nitrogen temperature so as to induce Bose-Einstein-condensation in the GGS, and to emit the light via polaritonic spontaneous emission and optionally lasing.

According to some embodiments of the invention the light source comprises an optical cavity.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A and 1B are schematic illustrations of an optoelectronic device, according to some embodiments of the present invention;

FIGS. 2A and 2B are schematic illustrations of an optoelectronic device, in embodiments of the invention in which the optoelectronic device comprises a cavity;

FIG. 3 is a schematic illustration of an optoelectronic device, in embodiments of the invention in which the optoelectronic device comprises more than one cavity;

FIGS. 4A and 4B are schematic illustrations of a light detection system, which can be used as a camera, according to some embodiments of the present invention;

FIG. 5 is a schematic illustration of an optoelectronic device, in an example embodiment in which a hexagonal boron nitride encapsulation is employed; and

FIG. 6 is a schematic illustration of an optoelectronic device having a cavity, in an example embodiment in which a hexagonal boron nitride encapsulation is employed.

### DESCRIPTION OF SPECIFIC EMBODIMENTS OF THE INVENTION

The present invention, in some embodiments thereof, relates to a handling of radiation and, more particularly, but not exclusively, to a method and system for emitting and/or detecting radiation in the terahertz (THz) range, preferably the long-wavelength-infrared (LWIR) range and the far-infrared (FIR) range.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

The Inventor realized that known systems that operate in the THz range are cumbersome and costly, because the response of conventional materials in the THz range is inadequate. The Inventor realized that this is one of the reasons for the sparsity of high-end and low-cost THz optoelectronic devices. The Inventor further realized that systems operating in the LWIR range are also bulky and expensive, and are therefore utilized mostly in research facilities and large laboratories.

The Inventor therefore devised a technique that can handle THz radiation, preferably LWIR and/or FIR radiation, and that can be utilized by a small size and a low cost system. The system of the present embodiments enjoys higher performance compared to known techniques.

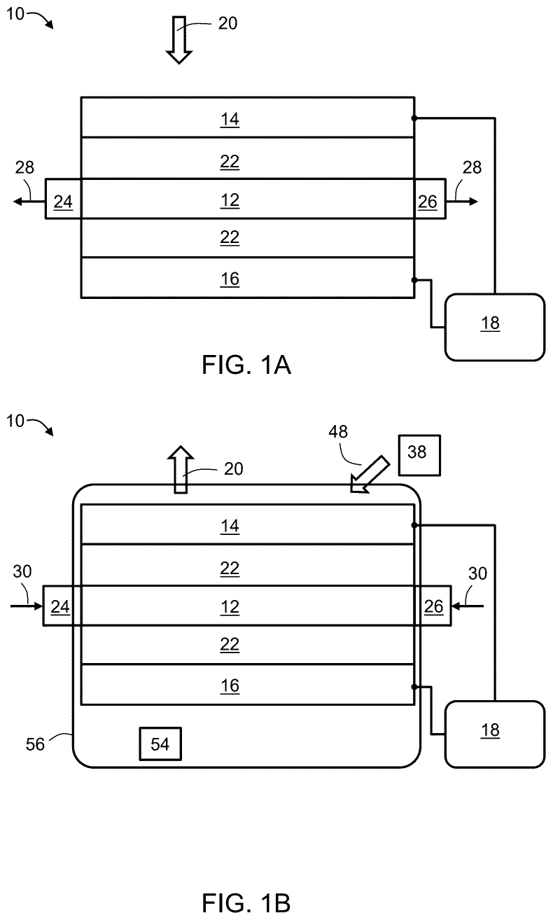

FIGS. 1A and 1B are schematic illustrations of an optoelectronic device 10, according to some embodiments of the present invention. Device 10 comprises a gapped graphene system (GGS) 12, a top gate electrode 14, a bottom gate electrode 16 and a controller 18.

Controller 18 can be, or can comprise, a circuit configured for applying a voltage bias between gate electrodes 14 and 16 so as to effect a bandgap in GGS 12. The bandgap is optionally and preferably selected to allow GGS 12 to receive (FIG. 1A) or emit (FIG. 1B) light 20 having a frequency within the range of from about 0.5 THz to about 35 THz. Preferably, the wavelength of light 20 is within a range that encompasses the long-wavelength-infrared (LWIR) range and the far-infrared (FIR) range. Alternatively, the wavelength of light 20 is within a range that encompasses the LWIR range but not the FIR range. Alternatively, the wavelength of light 20 is within a range that encompasses the FIR range but not the LWIR range.

As used herein the LWIR range refers to a range of wavelengths spanning from about 8 microns to about 30 microns.

As used herein the FIR range refers to a range of wavelengths spanning from about 30 microns to about 1000 microns.

Graphene is a 2-dimensional, semi-metallic, atomically-thin film in which carbon atoms are arranged into a sp² honeycomb lattice structurally relying on in-plane, covalent o-bonds. Single layer graphene is a gapless (bandgap-free) semimetal. When two or more single layer graphene are stacked vertically, they can interact with each other, for example, via their pi-bonds. Such a structure may also have a zero bandgap character. However, a bandgap can be introduced in such a structure when the inversion symmetry of two or more of the stacked layers is broken by an external electric field applied perpendicularly to the layers. The bandgap depends on the strength of the applied electric field.

GGS 12 therefore comprises two or more single layers of graphene that are stacked one on top of the other in a manner that allows opening and/or varying a bandgap of the stack upon application of an electric field in a direction perpendicular to the layers in the stack.

GGS 12 can be embodied in more than one way. One example of a GGS suitable for use as GGS 12 includes a Gapped Bilayer-Graphene (BLG). This structure comprises two single layers of graphene stacked on top of each other in an AB form or an AA form.

Another example of a GGS suitable for use as GGS 12 includes a Gapped Rhombohedral-Trilayer-Graphene (RTG). This structure comprises three single layers of graphene stacked on top of each other in a rhombohedral lattice arrangement. In this structure, the three graphene layers are not perfectly aligned on top of each other, but rather twisted at a certain angle relative to each other.

An additional example of a GGS suitable for use as GGS 12 includes a Twisted Double Bilayer Graphene (TDBG). This structure comprises two bilayer graphene structures stacked on top of each other, optionally and preferably, with a twist angle between the two bilayer graphene structures, to form a moiré pattern.

It is expected that during the life of a patent maturing from this application many relevant structures that comprise two or more layered of graphene and that have a tunable bandgap will be developed and the scope of the term GGS is intended to include all such new technologies a priori.

One or both of gate electrodes 14 and 16 is preferably transparent to an optical field of light 20. Representative examples of material suitable for use as gate electrodes 14 and 16, include, without limitation, indium tin oxide (ITO), fluorine tin oxide (FTO), indium-zinc-oxide, aluminum Zinc Oxide (AZO), single layer graphene, transparent and conductive polymer such as, but not limited to, poly(3,4-ethylenedioxythiophene) and poly(3-hexylthiophene). At least one of gate electrodes 14 and 16, more preferably both gate electrodes 14 and 16, are planar.

In some embodiments of the present invention GGS 12 is encapsulated by dielectric layers 22. Layers 22 can serve for protecting GGS 12 from the environment. Layers 22 can be made of any dielectric suitable for encapsulating graphene structure. Representative examples including, without limitation, hexagonal boron nitride (hBN), silicon dioxide (SiO₂), aluminum oxide (Al₂O₃), hafnium oxide (HfO₂), Titanium Dioxide (TiO₂), Zinc Oxide (ZnO) and the like.

Device 10 can comprise a source contact pad 24 and a drain contact pad 26, both contacting GGS 12 but are spaced apart from each other. For example, contact pads 24 and 26 can contact GGS 12 from two opposite lateral sides thereof. Both contact pads 24 and 26 are electrically conductive.

Device 10 can be used either as a light detector or as a light emitter. When used as a light detector (see FIG. 1A), a measuring circuit (not shown) is connected to contact pads 24 and 26. Controller 18 applies voltage to the gate electrodes 14 and 16 to open or vary the bandgap of GGS 12 allowing GGS 12 to receive light 20. Upon interaction of light 20 at a frequency that matches the bandgap, GGS 12 generates an electrical signal 28 which is then measured by the measuring circuit.

When used as a light emitter (see FIG. 1B), a bias circuit (not shown) is connected to contact pads 24 and 26. Controller 18 applies voltage to the gate electrodes 14 and 16 to open or vary the bandgap of GGS 12 allowing GGS 12 to emit light. The bias circuit serves as a pumping device, which injects electrical current 30 through GGS 12 to generate therein electron-hole pairs which emit light 20 upon recombination. Alternatively, the pumping device can comprise a laser source 38 configured to irradiate GGS 12 by a pump light beam 48 so as generate the electron-hole pairs by optical pumping.

In some embodiments of the present invention device 10 comprises a cooling system 54. In these embodiments, device 10 is optionally and preferably placed in a thermal encapsulation 56 that thermally isolates it from the environment. Preferably, system 54 cools device 10 to liquid-nitrogen temperature. The advantage of these embodiments is that at such a temperature Bose-Einstein-condensation is induced in GGS 12, and so light 20 can be emitted via polaritonic emissions.

Cooling system may employ coolant to achieve and maintain the desired temperatures. The coolant, in this context, refers to the substance or medium employed to absorb and carry away heat at least from GGS 12, thereby lowering its temperature. The coolant can be of any type known in the art. For example, the coolant can be a liquid nitrogen, which is readily available, cost-effective, and environmentally friendly. Liquid nitrogen is advantageous due to its exceptionally low boiling point and high cooling capacity. Liquid nitrogen undergoes a phase transition from a liquid to a gas as it absorbs heat from the surrounding environment. This phase transition absorbs a significant amount of heat during the transition, contributing to efficient cooling. The gaseous nitrogen produced during this process can be vented or recaptured and condensed back into a liquid for reuse, thus minimizing coolant wastage.

In some embodiments of the present invention controller 18 is configured to scan the voltage bias, so as to vary the bandgap. These embodiments are useful when it is desired to have an optoelectronic device with tunable properties. Thus, when device 10 is configured to receive light, the voltage scanning allows device 10 to select the light frequency at which a signal is generated, and when device 10 is configured to emit light, the voltage scanning allows device 10 to emit light at a selectable frequency.

Voltage scanning is particularly useful when optical detector 10 is used as a spectrometer. In these embodiments, the voltage scanning allows the spectrometer to detect, for each voltage point within the scan, an optical signal having a frequency that corresponds to the voltage point. The voltage scanning can span over a voltage range that corresponds to a spectrum encompassing the THz range, preferably the LWIR and/or FIR range, and/or any subrange thereof. Such a spectrometer can also be used as a photodetector for an optical signal at a specific frequency. In this case, the applied voltage bias is fixed at a value that corresponds to the specific frequency of interest.

It is appreciated that the measuring circuit and/or the bias circuit can be embodied within controller 18.

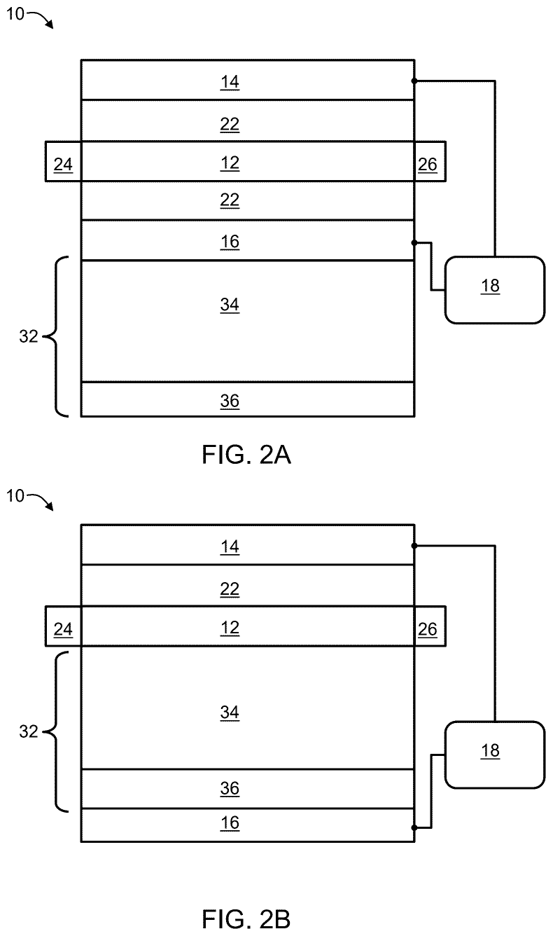

FIGS. 2A and 2B are schematic illustration of device 10 in embodiments of the invention in which device 10 comprises an optical cavity 32. Preferably the optical cavity includes a dielectric spacer 34 and a mirror 36, wherein dielectric spacer 34 is between mirror 36 and the structure including the GGS. In some embodiments of the present invention there is no dielectric layer 22 and no electrode between GGS 12 and cavity 32. In these embodiments GGS 12 is connected the upper surface of cavity 32 via van der Waals forces, and gate electrode is below cavity 32, as illustrated in FIG. 2B.

Dielectric spacer 34 can be made of any material suitable for use in optical systems configured to receive or emit light of specific frequency. Representative examples including, without limitation, zinc telluride, titanium dioxide, zinc oxide, boron phosphide, silicon-germanium, CVD diamond, hafnium nitride, and boron-aluminum nitride. In some embodiments of the present invention spacer 34 is made as a layered structure. For example, spacer 34 can be an alternating sequence of layers of different materials.

Mirror 36 is made of a material that is reflective to light having a frequency in the THz or LWIR or FIR range. Representative example of materials suitable for use with for mirror 36 include, without limitation, silicon, silicon dioxide, magnesium oxide, and the like.

A configuration with optical cavity 32 is particularly useful in embodiments in which it is desired to have an optoelectronic device with a further enhances selectivity to a particular range of frequencies, beyond the selectivity provided by the aforementioned electronic bandgap itself. An optical activity is therefore useful both in reception mode and in emission mode. In reception mode, the optical cavity is optionally and preferably designed and configured for enhancing an optical field at a frequency that is intended to be received by the device, and in emission mode, the optical cavity is optionally and preferably designed and configured for enhancing an optical field at a frequency that is intended to be emitted by the device.

Cavity 32 serves as a resonator, and its size along a direction perpendicular to the layers of GGS 12 can be selected according to a linear rescaling principle. For example, a device operating at a frequency ƒ can be fabricated using a cavity having twice the linear dimensions of a cavity of a device operating at a frequency of 2ƒ.

In some embodiments of the present invention cavity 32 is characterized by a quality factor Q of from about 10 to about 10000, more preferably from about 200 to about 5000, more preferably from about 400 to about 2500.

The quality factor Q of a cavity is defined as ratio between the resonance frequency and the resonance bandwidth (full width at half maximum of the resonance curve) of cavity 32.

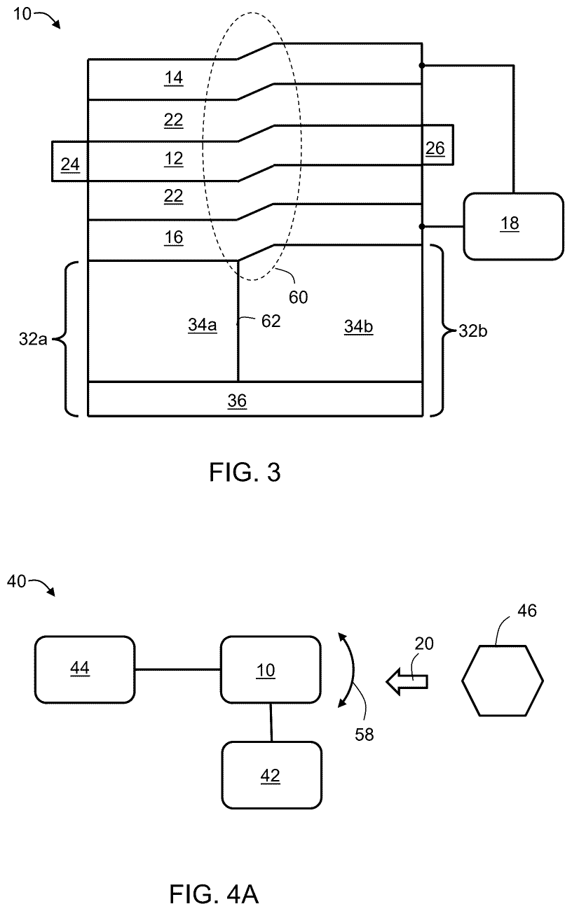

FIG. 3 is a schematic illustration of device 10 in embodiments of the invention in which device 10 comprises more than one optical cavity 32a, 32b. Both cavities can share the same mirror 36, as illustrated in FIG. 3, or each cavity can include a separate mirror. Each cavity has a dielectric spacer 34a 34b, and is preferably characterized by a different resonance frequency. This can be ensured by fabricating spacers with different sizes along the direction perpendicular to GGS 12, as illustrated in FIG. 3. In some embodiments of the present invention each optical cavity has a different Q factor. Optical cavities 32a, 32b are preferably arranged side-by-side. Since spacers 34a and 34b are at different heights, the layers above and/or below (above, in the illustration of FIG. 3, which is not to be considered as limiting), are arranged at different vertical positions, so as to ensure contact between adjacent layers. For example, these layers can deviate from planarity at a region 60 above and/or below the interface 62 between cavity 32a and cavity 32b.

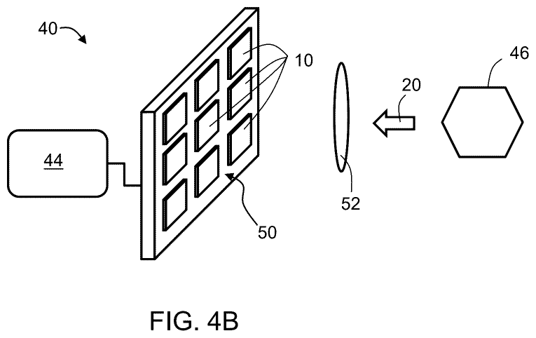

In some embodiments of the present invention, optoelectronic device 10 is employed in a camera capable of receiving from a scene or an object radiation in the THz range, preferably the LWIR and/or FIR range, or any subrange thereof, and imaging the scene or object based on the received radiation. Such a camera can be embodied in more than one way, as will now be explained with reference to FIGS. 4A and 4B.

FIG. 4A is a schematic illustration of a camera 40, according to some embodiments of the present invention. Camera 40 comprises the device 10 serving as an optical detector, a camera controller 42, and an image processor 44. Controller 42 spatially scans 58 an object or a scene 46 by device 10 to detect radiation 20 from each of multiple points over object or scene 46. This provides an array of detection signals, each corresponding to a different point over object or scene 46. The frequency of the radiation that is detected by device 10 is controlled by the voltage applied between electrodes 14 and 16. Camera controller can be combined with controller 18 in a single control system that is configured to control both and the spatial scanning and the applied voltage. The array of detection signals can be transmitted, optionally and preferably as a digital signal, to image processor 44 which generates from the array an image of the object or scene 46.

FIG. 4B is a schematic illustration of a camera 40, in embodiments of the invention in which an array 50 of optoelectronic devices is employed. In these embodiments camera 40 comprises array 50 of optical devices, wherein each of the devices is device 10 as further detailed hereinabove. The array 50 serves as a pixelated imager in which each device 10 or group of devices provides a separate signal corresponding to a separate picture-element of the image, preferably a single pixel of the image. Camera 40 also comprises optics 52 configured to focus radiation 20 from each of multiple points over object or scene 46 onto a different optical device 10 of array 50. Image processor 44 receives a respective array of detection signals from array 50 and generates from the array of detection signals an image of object or scene 46.

In any of the above embodiments of the camera, device(s) 10 can detect the radiation at a specific frequency, thus creating an image at a single frequency. Alternatively, the imaging process can be repeated for each of a plurality of frequencies (e.g., by executing voltage scanning for the voltage bias between the top and bottom gate electrodes as further detailed hereinabove), thus providing a plurality of single-frequency images, which can then be combined (e.g., superimposed) by the image processor.

Detection signals that correspond to different frequencies can be transmitted to image processor 44 serially. Alternatively, two or more of arrays of detection signals can be transmitted simultaneously to image processor 44 from respective two devices 10 that are configured to detect light at a different frequency range.

As used herein the term “about” refers to ±10 %

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

This Example describes various optoelectronic devices that utilize a gapped graphene system (GGS). The operations of the devices described herein are based on an excitonic response in the GGSs, which interacts with light at the THz spectral range, preferably the LWIR and/or FIR spectral range. The devices of the present embodiments are based on the excitation of excitons in a GGS that can be electrically tuned within in the LWIR and/or FIR spectrum, and the optical manipulation of the exciton, so as to facilitate detection and/or generation of radiation in the LWIR and/or FIR range.

In some embodiments of the present invention the optoelectronic devices are electrically controlled in a manner that allows them to be spectrally tunable over the entire range of 0.5-35THz or at any subrange thereof. The optoelectronic devices of the present embodiments operate at liquid-nitrogen temperature, unlike known systems that require liquid-helium cooling in order to function properly. This advantageously provides optoelectronic devices, which are compact, low-cost, and out-perform the current state-of-the-art.

The GGS can, in some embodiments of the present invention, be encapsulated in a dielectric material such as, but not limited to, hexagonal boron nitride (hBN) or the like.

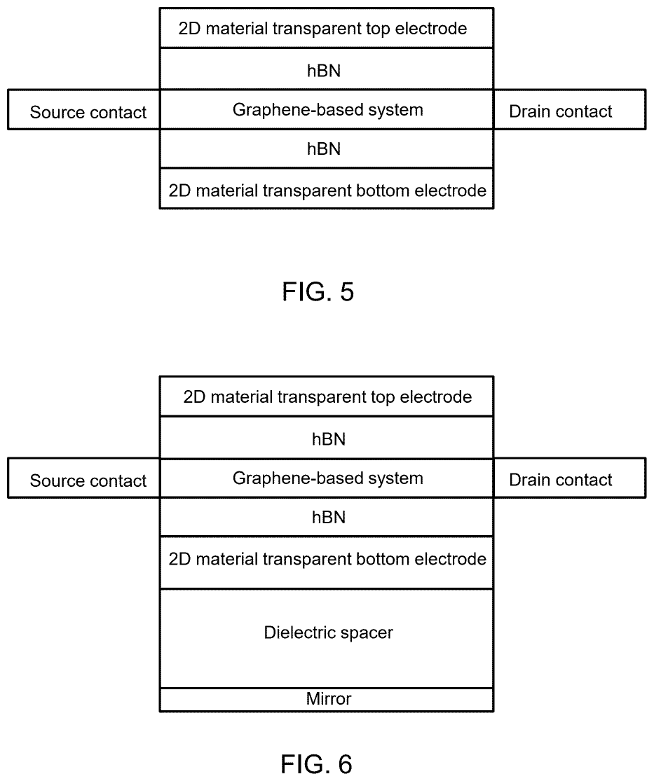

A representative illustration of a structure containing a GGS that is encapsulated in a dielectric material and that includes a source electrode, a drain electrode, a top gate electrode, and a bottom gate electrode is illustrated in FIG. 5.

Voltage bias applied between the top and bottom gates opens an electronic bandgap which is energy-dependent. This defines an energy level which can induce excitons in the CGS, once such level of energy is delivered to the CGS. Voltage applied between the source and drain electrodes can generate motion of charge carriers within the GGS.

A structure including a GGS, such as, but not limited to, the structure shown in FIG. 5 above can be used in various applications. Broadly speaking, the structure can be used in a reception mode in which the radiation from the environment of another source interacts with the structure to induce an electrical current between the source and the drain, or in emission mode in which radiation is emitted from the structure following electrical or optical excitation of the CGS.

In some embodiments of the present invention structure including a GGS, such as, but not limited to, the structure shown in FIG. 5 is optically coupled to an optical cavity, as illustrated in FIG. 6.

Some embodiments of the present invention provide an optoelectronic device useful for use as an optical detector of radiation in the THz range, preferably the LWIR and/or FIR range or any subrange thereof. The inventors found that use of optical cavity for such a device, can increase the percentage of radiation absorption of the frequency of interest by at least an order of magnitude, e.g., two orders of magnitude, compared to conventional devices. Thus, the optical detector of the present embodiments enjoys higher efficiency than known LWIR and FIR detectors.

The optical detector of the present embodiments can be preferably designed for a specific frequency to be detected. In these embodiments, the cavity is optimized to the specific frequency for achieving absorption of at least 90 % or at least 95 % or at least 99 % or the radiation, and for improving the detection sensitivity. Such optimization optionally and preferably takes into account the optical response of the excitons at the specific frequency, the optical response of the dielectric material of the dielectric spacer, the thickness of the cavity along a direction perpendicular to the mirror-spacer interface.

The optical detector can in some embodiments of the present invention comprise two or more cavities, each designed for a different frequency of a different frequency range.

In some embodiments of the present invention the structure is placed directly on the dielectric material of the cavity via van der Waals forces. Electrical contacts that are connected to the source and drain electrodes can be used for collecting the current induced by the impinging radiation, thus acting as a photodetector.

Some embodiments of the present invention provide an optoelectronic device useful for use, when operating at an emission mode, as a light source generating radiation in the THz range, preferably the LWIR and/or FIR range, or any subrange thereof.

The light source can emit the radiation via photoluminescence (PL) following optical pumping, or via electroluminescence (EL) following electrical pumping. The spectral range of the emission can be selected by selecting the voltage bias that is applied between the top and bottom gate electrodes. The light source of the present embodiments can include a GGS that is optionally and preferably encapsulated in a dielectric material, a top gate electrode, and a bottom gate electrode. In embodiments in which the radiation is via EL the light source also includes a source electrode, and a drain electrode. In embodiments in which the radiation is via PL the light source may optionally be devoid of source and drain electrodes. The emission mechanisms in the GGS of the present embodiments is Joule heating, wherein elevated electron temperatures that are caused by Joule heating leads to an increased thermal population of excitons in the GGS, which is followed by radiative recombination.

In some embodiments of the present invention the light source also comprises an optical cavity designed and constructed to enhance emission at a specific frequency or a specific frequency range.

In embodiments in which electrical pumping is employed, voltage is applied between the source and drain electrodes to generate current in the GGS at an amount that ensures Joule heating, and consequently emission of light by recombination of electron-hole pairs.

In embodiments in which optical pumping is employed, an external laser illuminate the GGS, wherein the energy of the external laser is higher than the bandgap gap created by means of the voltage bias between the top and bottom gate electrodes. The laser optically excite electron-hole pairs in the GGS, which in turn emit light upon recombination at the frequency set by the applied bias voltage.

In some embodiments of the present invention the light source is a polaritonic light source. The reactively large binding energies of the GGS excitons, corresponding to about 20% of the bandgap size, and their relatively large oscillator strength, allow reaching the strong and ultra-strong coupling regimes. For such coupling strengths, bosonic exciton-polaritons and Bose-Einstein-condensation (BEC) can be achieved. These phenomena are exploited according to some embodiments of the present invention to polaritonic light emissions or polaritonic lasing. In cases in which it is desired to achieve the BEC, the GGS is cooled to liquid-nitrogen temperature and is electrically doped with charge carriers via the gate electrodes, while maintaining the open electronic bandgap, thus establishing the condition for spontaneous light emission at a frequency that corresponds to the band gap. The emission frequency can be tuned by means of the applied voltage bias and by electrically or optically pumping the GGS, as further detailed hereinabove.

In embodiments in which an optical cavity is employed, the cavity can be a high-Q optical cavity that allows coupling the excitons to the high-Q optical mode of the cavity to provide lasing. The laser can be pumped electrically or optically, and its optical frequency can be tunes by means of the applied voltage bias as further detailed hereinabove.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. An optoelectronic device, comprising a gapped graphene system (GGS), a top gate electrode, a bottom gate electrode, a cooling system configured to cool said GGS, and a controller configured for applying a voltage bias between said gate electrodes to induce excitons and effect a bandgap in said GGS, wherein said voltage bias is selected to electrically tune said excitons to ensure that said bandgap allows said GGS to receive or emit light having a frequency within the range of from about 0.5 THz to about 35 THz.

2. The optoelectronic device according to claim 1, comprising an optical cavity.

3. The optoelectronic device according to claim 1, comprising at least two optical cavities, each being characterized by a different resonance frequency.

4. The optoelectronic device according to claim 3, wherein each optical cavity has a different Q factor.

5. The optoelectronic device according to claim 2, wherein said GGS is connected to an end of said optical cavity via van der Waals forces.

6. The optoelectronic device according to claim 1, wherein said controller is configured to scan said voltage bias, so as to vary said bandgap.

7. (canceled)

8. The optoelectronic device according to claim 1, wherein said GGS is encapsulated in a dielectric encapsulation.

9. (canceled)

10. An optical detector comprising the optoelectronic device according to claim 1, and a source electrode and a drain electrode connected to said GGS.

11. (canceled)

12. A camera, comprising the optical detector according to claim 10 and an image processor, wherein said controller is configured to spatially scan an object or a scene to detect radiation from each of multiple points over said object or scene, thereby providing an array of detection signals, and wherein said image processor is configured to generates from said array of detection signals an image of said object or scene.

13. (canceled)

14. A camera, comprising an array of optical detectors according to claim 10, an image processor, and optics configured to focus radiation from each of multiple points over said object or scene onto a different optical detector of said array, wherein said image processor is configured to receive a respective array of detection signals from said array of detectors and to generate from said array of detection signals an image of said object or scene.

15. (canceled)

16. The camera according to claim 12, wherein said image processor is configured to receive a plurality of arrays of detection signals, each corresponding to a different frequency of said radiation, and to generate said from a combination of said arrays of detection signals.

17. (canceled)

18. The camera according to claim 16, wherein said plurality of arrays of detection signals are transmitted serially to said image processor.

19. (canceled)

20. The camera according to claim 16, wherein at least two of said plurality of arrays of detection signals are transmitted simultaneously to said image processor from a respective two optical detectors each configured to detect light at a different frequency range.

21. (canceled)

22. A light source, comprising the optoelectronic device according to claim 1, and pumping device configured to generate in said GGS electron-hole pairs which emit light upon recombination.

23. (canceled)

24. The light source according to claim 22, wherein said pumping device comprises a source electrode and a drain electrode connected to said GGS, and wherein said controller is also configured to inject electrical current into said GGS via said source and drain electrodes, thereby to electrically pump said GGS.

25. (canceled)

26. The light source according to claim 22, wherein said pumping device comprises a laser source configured to irradiate said GGS to optically pump said GGS.

27. (canceled)

28. The light source according to claim 22, comprising a cooling system configured to liquid-nitrogen temperature so as to induce Bose-Einstein-condensation in said GGS, and to emit said light via polaritonic emissions.

29. (canceled)
